(19) United States
(12) Patent Application Publication
(10) Pub. No.: US 2011/0204942 A1
(43) Pub. Date: Aug. 25, 2011

(54) CLOCK CONTROL CIRCUIT AND SEMICONDUCTOR DEVICE INCLUDING THE SAME

(75) Inventors: Tsuneo Abe, Tokyo (JP); Atsuko Monma, Tokyo (JP)

(73) Assignee: Elpida Memory, Inc., Tokyo (JP)

(21) Appl. No.: 13/033,284

(22) Filed: Feb. 23, 2011

(30) Foreign Application Priority Data
Feb. 24, 2010 (JP) 2010-039043

(51) Int. Cl. H03L 7/06

(52) U.S. Cl. 327/158

(57) ABSTRACT

A clock control circuit includes: a phase determination circuit that generates a phase determination signal based on a phase of an external clock signal; a counter circuit having a count value updated based on a logic level of the phase determination signal; a delay line that generates an internal clock signal by delaying the external clock signal based on the count value; and a pitch adjustment circuit that sets an update pitch of the counter circuit to be twice as high as a minimum pitch in a period in which the phase determination signal has no change, and sets the update pitch of the counter circuit to the minimum pitch in response to a change in the phase determination signal. With this configuration, it is possible to realize quick and highly accurate locking of a DLL circuit.

### BACKGROUND OF THE INVENTION

1. Field of the Invention

The present invention relates to a clock control circuit and a semiconductor device including the same, and more particularly relates to a clock control circuit, such as a DLL (Delay Locked Loop) circuit or a duty-cycle correction circuit, for adjusting a phase or a duty cycle of a clock signal and a semiconductor device including the clock control circuit.

2. Description of Related Art

In recent years, synchronous memories that operate synchronously with clocks have been widely used as a main memory of a personal computer or the like. Among these memories, a DDR (Double Data Rate) synchronous memory needs a DLL circuit for generating an internal clock signal synchronous with an external clock signal as an essential element, because it is necessary to accurately synchronize input or output data with the external clock signal (see Japanese Patent Application Laid-open No. 2008-217947).

The DLL circuit includes a counter circuit a count value of which is updated based on a phase of an external clock signal, and a delay line that generates an internal clock signal by delaying the external clock signal based on the count value of the counter circuit. The counter circuit updates the count value in predetermined sampling cycles. Accordingly, when a phase determination result is temporarily inverted by the influence of noise or the like at a timing of updating the count value, the count value is updated in an opposite direction to an original update direction. That is, a delay amount of the delay line is decreased although being supposed to be increased or conversely the delay amount is increased although being supposed to be decreased.

Furthermore, a jitter component is often superimposed on the external clock signal. The jitter component represents a fluctuation in a clock frequency and this fluctuation has a predetermined frequency. When the jitter component affects the DLL circuit, the DLL circuit often falls into a loop of alternately repeating counting up and down despite a great phase shift and cannot escape from the state.

Meanwhile, a period for locking the DLL circuit is specified by corresponding standards. Therefore, when the delay line is adjusted in the opposite direction due to the influence of noise or the DLL circuit falls into a loop due to the influence of the jitter component, the DLL circuit cannot be locked within the period specified by the standards.

As described above, the conventional DLL circuit has the following problem. That is, the conventional DLL circuit cannot be correctly locked if being affected by noise or a jitter component. The problem of this type is not limited to DLL circuits but also occurs to other types of clock control circuits that control clock signals such as a duty-cycle correction circuit for correcting a duty cycle of an internal clock signal. That is, also the duty-cycle correction circuit is often incapable of adjusting the internal clock signal to have a desired duty cycle if being affected by noise or a jitter component.

### SUMMARY

In one embodiment, there is provided a clock control circuit that includes: a phase determination circuit that generates a phase determination signal based on a phase of a first clock signal; a counter circuit having a count value updated for every sampling cycle based on the phase determination signal; a first delay line that generates a second clock signal by delaying the first clock signal based on the count value; a first invalidation circuit that invalidates a subsequent change of the phase determination signal in a same sampling cycle in response to a fact that the phase determination signal indicates a first logic level; and a first pitch adjustment circuit that changes an update pitch of the counter circuit based on a fact that the phase determination signal indicates a second logic level.

Further, in one embodiment, there is provided a semiconductor device that includes: the above clock control circuit; an output buffer that outputs an external output signal synchronously with the second clock signal; and a replica buffer that is substantially identical in circuit configuration to the output buffer, and outputs the third clock Signal synchronously with the second clock signal.

In another embodiment, there is provided a clock control circuit that includes: a phase determination circuit that generates a phase determination signal based on a phase of a first clock signal; a counter circuit having a count value updated based on a logic level of the phase determination signal; a delay line that generates a second clock signal by delaying the first clock signal based on the count value; and a pitch adjustment circuit that sets an update pitch of the counter circuit to a first pitch in a period in which the phase determination signal has no change, and sets the update pitch of the counter circuit to a second pitch in response to a change in the phase determination signal, where the first pitch being a relatively high pitch and the second pitch being a relatively low pitch.

In still another embodiment, there is provided a clock control, circuit that includes: a phase determination circuit that generates a phase determination signal based on a phase of a first clock signal; a counter circuit having a count value updated based on a logic level of the phase determination signal; a delay line that generates a second clock signal by delaying the first clock signal based on the count value; and a pitch adjustment circuit that changes an update pitch of the counter circuit from a relatively low second pitch to a relatively high first pitch when the phase determination signal has no change for a predetermined period.

According to the present invention, when the determination signal changes in a sampling cycle, the invalidation circuit fixes the phase determination signal to a predetermined logic level, so that it is possible to eliminate a component such as noise or a jitter component that affects the phase determination signal in a short cycle. Furthermore, the change amount of the count value (update pitch) that indicates the delay amount of the delay line is appropriately changed according to the change in the phase determination signal, thereby making it possible to adjust the phase of the clock signal without any problems even with the presence of a clock in a short cycle. With this configuration, when the clock control circuit according to the present invention is applied to a DLL circuit, it is possible to prevent a phenomenon that the DLL circuit is not locked for a long period of time. Moreover, when the clock control circuit according to the present invention is applied to a duty-cycle correction circuit, it is possible to prevent a phenomenon that an internal clock signal cannot be adjusted to have a desired duty cycle for a long period of time.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a block diagram showing a configuration of a semiconductor device 10 according to a first embodiment of the present invention;

FIG. 2 is a circuit diagram of an invalidation circuit 200;

FIG. 3 is a circuit diagram of a pitch adjustment circuit 300;

FIG. 4 is a circuit diagram showing a configuration example of a counter circuit 130;

FIG. 5 is a timing chart showing an operation performed by a DLL circuit 100 according to the first embodiment;

FIG. 6 is a circuit diagram of an invalidation circuit 200;

FIG. 7 is a circuit diagram of a pitch adjustment circuit 300a;

FIG. 8 is a timing chart showing an operation of a DLL circuit according to a second embodiment;

FIG. 9 is a block diagram showing a configuration of a semiconductor device 30 according to a third embodiment;

FIG. 10 is a circuit diagram of a pitch adjustment circuit 400;

FIG. 11 is a timing chart showing an operation of a DLL circuit according to the third embodiment;

FIG. 12 is a block diagram showing a configuration of a semiconductor device 40 according to a fourth embodiment;

FIG. 13 is a block diagram showing a configuration of a semiconductor device 50 according to a fifth embodiment;

FIG. 14 is a block diagram showing a configuration of a semiconductor device 60 according to a sixth embodiment; and

FIG. 15 is a block diagram showing a configuration of a semiconductor device 70 according to a seventh embodiment.

### DETAILED DESCRIPTION OF THE EMBODIMENTS

Preferred embodiments of the present invention will be explained below in detail with reference to the accompanying drawings.

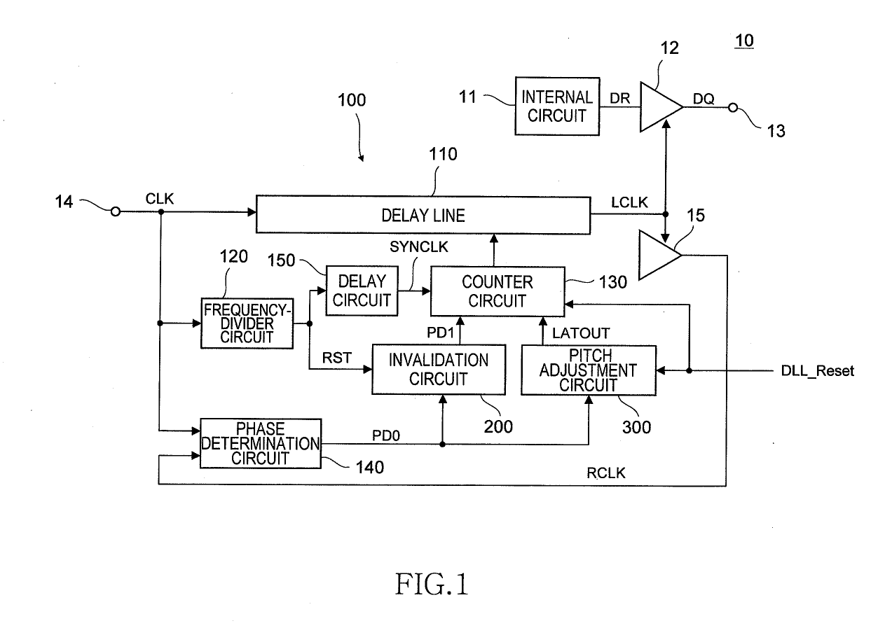

FIG. 1 is a block diagram showing a configuration of a semiconductor device 10 according to a first embodiment of the present invention.

As shown in FIG. 1, the semiconductor device 10 according to the first embodiment includes an internal circuit 11 that outputs an internal output signal DR, an output buffer 12 that outputs an external output signal DQ based on the internal output signal DR, and a DLL circuit 100 that controls an operation timing of the output buffer 12. The internal circuit 11 differs according to the type of the semiconductor device 10. For example, when the semiconductor device 10 according to the first embodiment is a DRAM, the internal circuit 11 includes a memory cell array, a column switch, a read amplifier or the like.

The output buffer 12 is a circuit that outputs the external output signal DQ to outside via an output terminal 13, and an output timing of the external output signal DQ needs to be synchronous with an external clock signal CLK (first clock signal) input via a clock terminal 14. The DLL circuit 100 controls the operation timing of the output buffer 12. A configuration of the DLL circuit 100 is described below in detail.

As shown in FIG. 1, the DLL circuit 100 includes a delay line 110, a frequency-divider circuit 120, a counter circuit 130, a phase determination circuit 140, an invalidation circuit 200, and a pitch adjustment circuit 300.

The delay line 110 is a circuit that generates an internal clock signal LCLK (second clock signal) by delaying the external clock signal CLK. Although not particularly limited, the delay line 110 preferably includes a coarse delay line that delays the external clock signal CLK at a relatively coarse adjustment pitch and a fine delay line that delays the external clock signal CLK at a relatively fine adjustment pitch. The external clock signal input to the delay line 110 is not always the external clock signal CLK itself but a signal obtained by receiver's buffering the external clock signal CLK can be input to the delay line 110.

As shown in FIG. 1, the internal clock signal LCLK is supplied to the output buffer 12 and a replica buffer 15. As described above, the output buffer 12 is a circuit that receives the internal output signal DR supplied from the internal circuit 11 and supplies this internal output signal DR to the output terminal 13 as the external output signal DQ. The replica buffer 15 is a circuit that is substantially identical in circuit configuration to the output buffer 12 and outputs a replica clock signal RCLK (third clock signal) synchronously with the internal clock signal LCLK. This enables a phase of the replica clock signal RCLK to accurately match to that of the external output signal DQ. However, sizes of transistors constituting the replica buffer 15 are not necessarily identical to those of transistors constituting the output buffer 12. As long as the replica buffer 15 is substantially equal in impedance to the output buffer 12, shrinking transistors can be used as constituent elements of the replica buffer 15.

The frequency-divider circuit 120 is a circuit that generates a reset signal RST that is a one-shot pulse by dividing a frequency of the external clock signal CLK. The reset signal RST is supplied to the invalidation circuit 200 and to the delay circuit 150. The delay circuit 150 is a circuit that generates an update timing signal SYNCLK by delaying the reset signal RST. The update timing signal SYNCLK is supplied to the counter circuit 130 and used as a synchronizing signal indicating a timing of updating a count value of the counter circuit 130. Therefore, an activation cycle of the update timing signal SYNCLK is defined as a sampling cycle of the DLL circuit 100. Preferably, a delay amount of the delay circuit 150 is slightly shorter than the sampling cycle.

Reasons for using the frequency-divider circuit 120 for generating the reset signal RST are as follows. It takes a fixed period of time to update the counter circuit 130 and to change the delay amount of the delay line 110. It is also difficult to update the counter circuit 130 and to change the delay amount of the delay line 110 for every cycle of the external clock signal CLK. Furthermore, when the counter circuit 130 is updated and the delay amount of the delay line 110 is changed too often more than necessary, power consumption greatly increases.

The counter circuit 130 is a circuit that sets the delay amount of the delay line 110 and the count value of the counter circuit 130 is updated synchronously with the update timing signal SYNCLK. An increase or a decrease in the count value is set based on a phase determination signal PD1 supplied from the invalidation circuit 200. That is, when the phase determination signal PD1 indicates counting up (a high level), the counter circuit 130 counts up the count value thereof synchronously with the update timing signal SYNCLK, thereby increasing the delay amount of the delay line 110. On the other hand, when the phase determination signal PD1 indicates counting down (a low level), the counter circuit 130 counts down the count value thereof synchronously with the update timing signal SYNCLK, thereby decreasing the delay amount of the delay line 110.

A reset signal DLL_Reset and a pitch designation signal LATOUT are also supplied to the counter circuit 130. The reset signal DLL_Reset is a signal that resets the DLL circuit 100. When the reset signal DLL_Reset is activated, the count value of the counter circuit 130 is initialized to a preset value. The pitch designation signal LATOUT is a signal generated by the pitch adjustment circuit 300. When the pitch designation signal LATOUT is at a low level, an update pitch of the counter circuit 130 (a count-up amount or a count-down amount of the count value synchronously with the update timing signal SYNCLK) is set to a minimum pitch. When the pitch designation signal LATOUT is at a high level, the update pitch of the counter circuit 130 is set to twice as high as the minimum pitch.

The phase determination circuit 140 is a circuit that detects a phase difference between the external clock signal CLK and the replica clock signal RCLK. As described above, the phase of the replica clock signal RCLK is adjusted by the delay line 110 so as to be matched to that of the external output signal DQ. However, the phases of the both signals RCLK and DQ change with passage of time due to such changes as changes in parameters such as voltage and temperature that affect the delay amount of the delay line 110 and a change in the external clock signal CLK itself. The phase determination circuit 140 detects such changes and determines whether the replica clock signal RCLK is advanced or delayed with respect to the external clock signal CLK. The phase determination circuit 140 makes this determination for every cycle of the external clock signal CLK and supplies a determination result, as a phase determination signal PD0, to the invalidation circuit 200 and the pitch adjustment circuit 300.

The invalidation circuit 200 is a circuit that receives the phase determination signal PD0 and the reset signal RST and generates the phase determination signal PD1 based on these signals PD0 and RST.

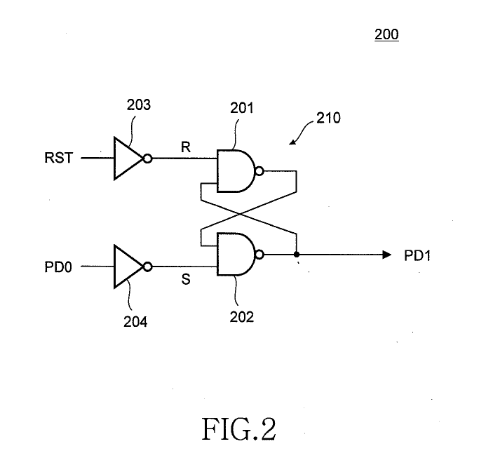

FIG. 2 is a circuit diagram of the invalidation circuit 200.

As shown in FIG. 2, the invalidation circuit 200 includes an SR latch circuit 210 constituted by cross-coupled NAND circuits 201 and 202, an inverter 203 that inverts the reset signal RST and supplies the inverted reset signal to a reset input terminal (R) of the SR latch circuit 210, and an inverter 204 that inverts the phase determination signal PD0 and supplies the inverted phase determination signal to a set input terminal (S) of the SR latch circuit 210.

With this configuration, when the phase determination signal PD0 is at a high level, then the SR latch circuit 210 is in a set state irrespective of a logic level of the reset signal RST, and the phase determination signal PD1 output from the SR latch circuit 210 is at a high level. In this case, the fact that the phase determination signal PD0 is at a high level corresponds to a case where the phase determination circuit 140 detects that the phase of the replica clock signal RCLK is advanced with respect to that of the external clock signal CLK. That is, the fact that the phase determination signal PD0 is at a high level corresponds to a case where it is necessary to increase the delay amount of the delay line 110.

On the other hand, when the reset signal RST is at a high level and the phase determination signal PD0 is at a low level, then the SR latch circuit 210 is in a reset state, and the phase determination signal PD1 output from the SR latch circuit 210 is at a low level. In this case, the fact that the phase determination signal PD0 is at a low level corresponds to a case where the phase determination circuit 140 detects that the phase of the replica clock signal RCLK is delayed with respect to that of the external clock signal CLK. That is, the fact that the phase determination signal PD0 is at a low level corresponds to a case where it is necessary to decrease the delay amount of the delay line 110.

Consequently, after resetting of the SR latch circuit 210, when the phase determination signal PD0 is at a high level, the SR latch circuit 210 is set. Thereafter, even when the phase determination signal PD0 changes to be a low level, the change is made invalid. That is, until the SR latch circuit 210 is reset after being set, the level of the phase determination signal PD1 output from the invalidation circuit 200 is fixed to high when the phase determination signal PD0 is at a high level even once. In addition, the state where the phase determination signal PD1 is at a low level is limited to a period in which the phase determination signal PD0 is kept at a low level after the SR latch circuit 210 is reset.

Referring back to FIG. 1, the pitch adjustment circuit 300 is a circuit that receives the phase determination signal PD0 and the reset signal DLL_Reset and generates the pitch designation signal LATOUT based on these signals PD0 and DLL_Reset.

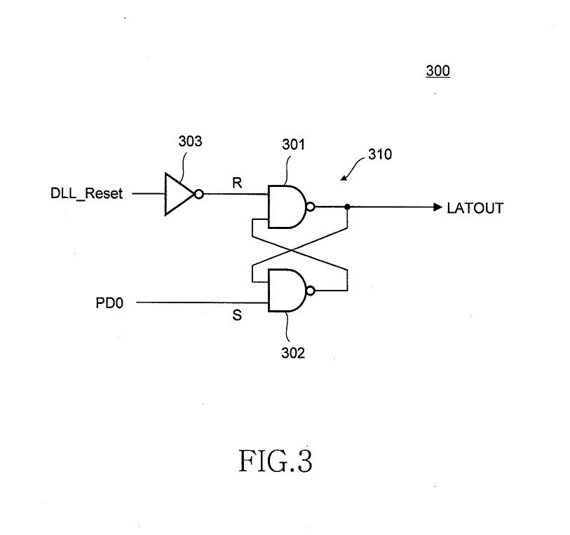

FIG. 3 is a circuit diagram of the pitch adjustment circuit 300.

As shown in FIG. 3, the pitch adjustment circuit 300 includes an SR latch circuit 310 constituted by cross-coupled NAND circuits 301 and 302 and an inverter 303 that inverts the reset signal DLL_Reset and supplies the inverted reset signal to a reset input terminal (R) of the SR latch circuit 310. The phase determination signal PD0 is input to a set input terminal (S) of the SR latch circuit 310.

With this configuration, when the reset signal DLL_Reset is at a high level, then the SR latch circuit 310 is in a reset state irrespective of a logic level of the phase determination signal PD0, and the pitch designation signal LATOUT output from the SR latch circuit 310 is at a high level. On the other hand, when the reset signal DLL_Reset is at a low level and the phase determination signal PD0 is at a low level, then the SR latch circuit 310 is in a set state and the pitch designation signal LATOUT output therefrom is at a low level.

Consequently, when the SR latch circuit 310 is reset, the pitch designation signal LATOUT is at a high level. Thereafter, when the level of the phase determination signal PD0 changes from high to low, the pitch designation signal LATOUT is at a low level. As described above, when the pitch designation signal LATOUT is at a high level, the update pitch of the counter circuit 130 is set to twice as fast as the minimum pitch.

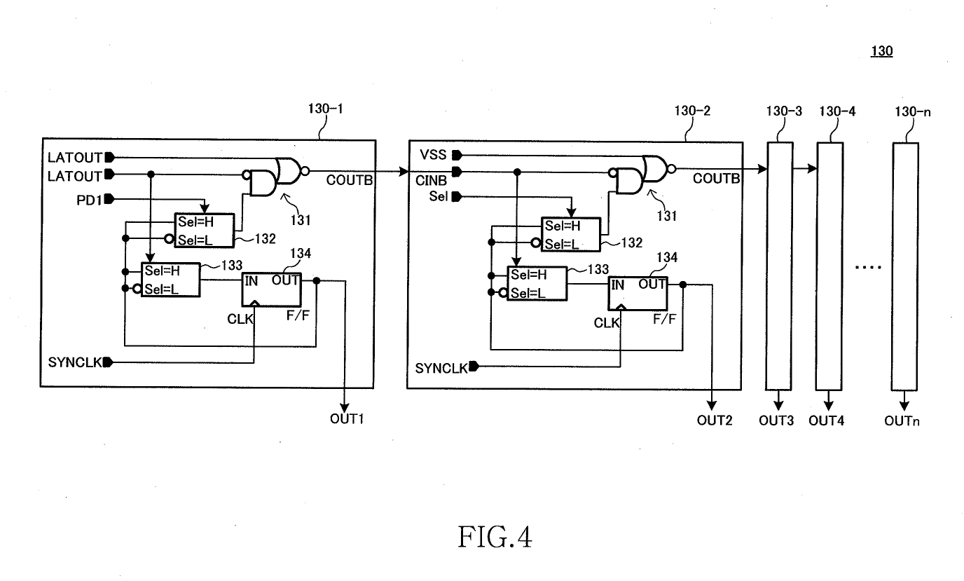

FIG. 4 is a circuit diagram showing a configuration example of the counter circuit 130.

As shown in FIG. 4, the counter circuit 130 is configured to include a plurality of bit count circuits 130-1 to 130-n. The number (n) of the bit count circuits 130-1 to 130-n constituting the counter circuit 130 is equal to the number of bits of the count value. Output bits OUT1 to OUTn output from the bit count circuits 130-1 to 130-n correspond to bits of the count value, respectively.

The bit count circuits 130-0 to 130-n are identical in circuit configuration and each of the bit count circuits 130-0 to 130-n is configured to include a complex gate circuit 131, selectors 132 and 133, and a latch circuit 134. An output from the complex gate circuit 131 is used as an input signal input to the complex gate circuit 131 included in the next-stage bit count circuit.

Specifically, the bit designation signal LATOUT and an output signal from the selector 132 are input to the complex gate circuit 131 of the first-stage bit count circuit 130-1. On the other hand, output signals from the complex gate circuits 131 included in the prior-stage bit count circuits in place of the pitch designation signal LATOUT as well as a signal fixed to VSS level are input to the complex gate circuits 131 of the respective stages of bit count circuits 130-2 to 130-n subsequent to the first-stage bit count circuit 130-1.

With this configuration, when the pitch designation signal LATOUT is at a low level, the update pitch of the counter circuit 130 is the minimum pitch because the bit count circuit 130-1 corresponding to a least significant bit (LSB) is an update target. On the other hand, when the pitch designation signal LATOUT is at a high level, the update pitch of the circuit 130 is twice as high as the minimum pitch because the bit count circuit 130-2 corresponding to a second most significant bit is an update target.

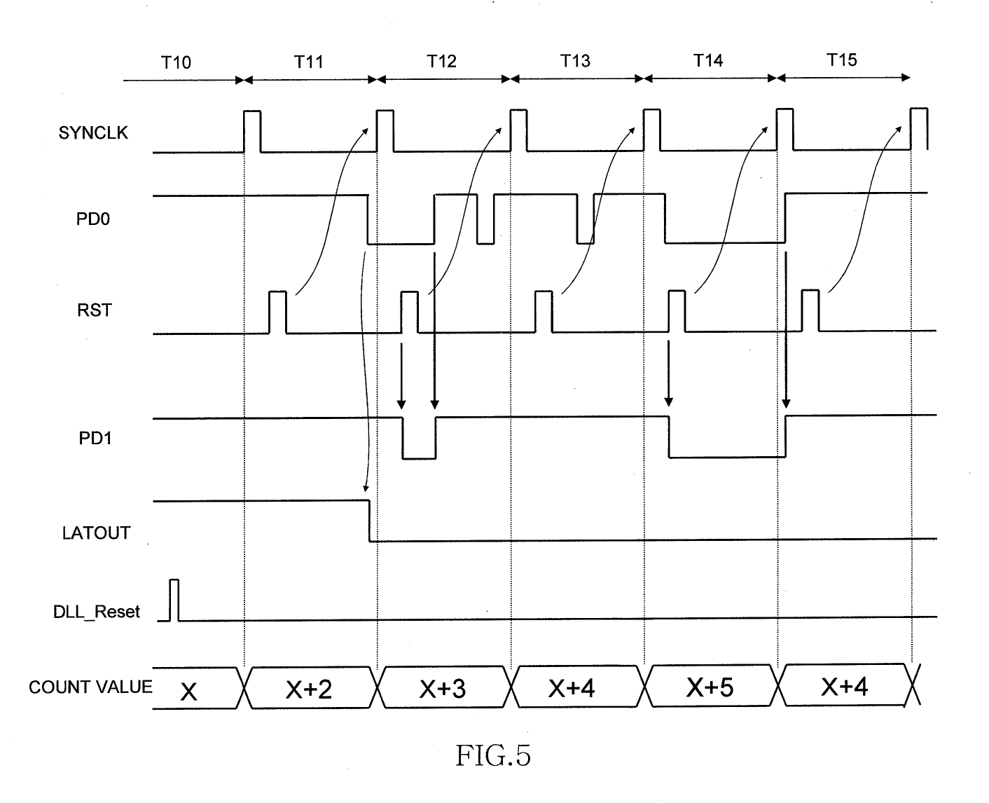

FIG. 5 is a timing chart showing an operation performed by the DLL circuit 100 according to the first embodiment.

In an example shown in FIG. 5, the delay amount of the delay circuit 150 is set slightly shorter than the sampling cycle. Accordingly, when the update timing signal SYNCLK is activated, the reset signal RST is activated right after activation of the update timing signal SYNCLK. This means that when the count value of the counter circuit 130 is updated, the reset signal RST is activated right after the update of the count value of the counter circuit 130.

First, when the reset signal DLL_Reset that is a one-shot pulse is activated in a period T10, the pitch designation signal LATOUT is at a high level. The update pitch of the counter circuit 130 is thereby set to be twice as high as the minimum pitch. In the example shown in FIG. 5, the level of the phase determination signal PD0 has a transition from high to low halfway along a sampling cycle T11, and the pitch designation signal LATOUT turns to a low level at the transition timing. The update pitch of the counter circuit 130 is thereby set to the minimum pitch.

As shown in FIG. 5, the phase determination signal PD0 is at a high level at timings at which the reset signal RST is activated in sampling cycles T11, T13, and T15, respectively. Accordingly, the SR latch circuit 210 included in the invalidation circuit 200 is not reset. In this case, the SR latch circuit 210 is kept in the set state as before. Therefore, even when the phase determination signal PD0 changes to a low level halfway as shown in the sampling cycle T13, then such a change is made invalid and the phase determination signal PD1 is kept at a high level. As a result, at a next timing at which the update timing signal SYNCLK is updated, the count value of the counter circuit 130 is forcibly counted up. That is, the delay amount of the delay line 110 is forcibly increased.

On the other hand, at timings at which the reset signal RST is activated in sampling cycles T12 and T14, the phase determination signal PD0 is at a low level and the SR latch circuit 210 is therefore reset synchronously with the reset signal RST. The phase determination signal PD1 output from the invalidation circuit 200 thereby changes to be a low level.

However, in the sampling cycle T12, the phase determination signal PD0 then changes to be a high level and, therefore the SR latch circuit 210 is made in the set state again in response to the change of the phase determination signal PD0. The phase determination signal PD1 thereby returns to be a high level. Thereafter, even when the phase determination signal PD0 changes to be a low level in the same sampling cycle, then such a change is made invalid and the phase determination signal PD1 is kept at a high level. As a result, at a next timing at which the update timing signal SYNCLK is activated, the count value of the counter circuit 130 is forcibly counted up. That is, the delay amount of the delay line 110 is forcibly increased.

Meanwhile, in the sampling cycle T14, after the SR latch circuit 210 is reset by activation of the reset signal RST, the phase determination signal PD0 is kept to be a low level until a next timing at which the update timing signal SYNCLK is activated. The SR latch circuit 210 is thereby kept in the reset state, and therefore the count value of the counter circuit 130 is counted down at a next timing at which the update timing signal SYNCLK is activated. That is, the delay amount of the delay line 110 is decreased.

As described above, in the first embodiment, the case where the count value of the counter circuit 130 is counted down is limited to the case shown in the sampling cycle T14, that is, the case where the phase determination signal PD0 is kept at a low level after the SR latch circuit 210 is reset by activation of the reset signal RST until the next timing at which the update timing signal SYNCLK is activated. In other cases, the invalidation circuit 200 invalidates any changes in the phase determination circuit PD0 and the count value of the counter circuit 130 is forcibly counted up.

With this configuration, the component such as noise or the jitter component that affects the phase determination signal PD0 in a short cycle is eliminated. This can prevent a phenomenon that the DLL circuit 100 is not locked for a long period of time.

Moreover, the pitch designation signal LATOUT sets the count-up amount or count-down amount (that is, the update pitch) of the counter circuit 130. In the example shown in FIG. 5, at the first time of activating the update timing signal SYNCLK, the pitch designation signal LATOUT is at a high level, and therefore the count value of the counter circuit 130 is counted up at the update pitch that is twice as high as the minimum pitch (X→X+2). At the second and following timings of activating the update timing signal SYNCLK, the pitch designation signal LATOUT is at a low level, and therefore the count value of the counter circuit 130 is counted down at the update pitch equal to the minimum pitch.

Accordingly, in the period in which the phase determination signal PD0 has no change right after activating the reset signal DLL_Reset, the update pitch of the counter circuit 130 is twice as high as the minimum pitch, so that the phase of the external clock signal CLK and that of the replica clock signal RCLK can be made to quickly approach each other. Further, when the phase determination signal PD0 changes, that is, when the phase determination circuit 140 detects that an active edge of the replica clock signal RCLK exceeds an active edge of the external clock signal CLK, the update pitch of the counter circuit 130 is equal to the minimum pitch, so that the phase difference between the replica clock signal RCLK and the external clock signal CLK can be matched with high degree of accuracy. Therefore, according to the first embodiment, even when it takes a long time before the DLL circuit 100 is locked, for example, even when the frequency of the external clock signal CLK is relatively low, it is possible to quickly lock the DLL circuit 100.

In the first embodiment, a higher priority is given to counting-up of the counter circuit 130 than counting-down thereof. Accordingly, even when it takes a shorter time to lock the DLL circuit 100 by allowing the counter circuit 130 to count down (when an advanced amount of the replica clock signal RCLK with respect to the external clock signal CLK is larger than a delay amount thereof), the DLL circuit 100 is often locked by allowing the counter circuit 130 to continue counting up. In this case, despite a slightly longer time before the DLL circuit 100 is locked, at least the problem that the DLL circuit 100 falls into a loop of alternately repeating counting up and down does not occur. Besides, the adjustment operation of adjusting the update pitch of the counter circuit 130 is performed at the update pitch twice as high as the minimum pitch until the active edge of the replica clock signal RCLK exceeds that of the external clock signal CLK. Therefore, it is possible to complete locking the DLL circuit 100 within the period specified by the standards.

A second embodiment of the present invention is explained next.

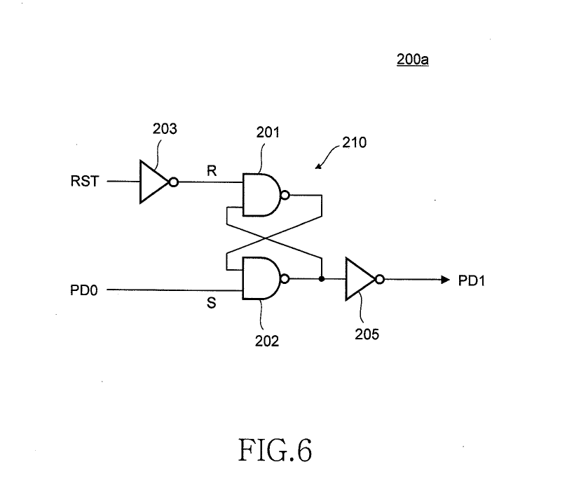

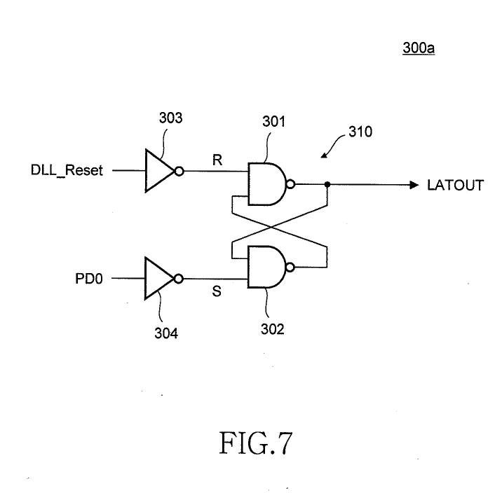

FIG. 6 is a circuit diagram of an invalidation circuit 200a used in the second embodiment. FIG. 7 is a circuit diagram of a pitch adjustment circuit 300a used in the second embodiment. While the second embodiment differs from the first embodiment shown in FIG. 1 in that the invalidation circuit 200a replaces the invalidation circuit 200 and in that the pitch adjustment circuit 300a replaces the pitch adjustment circuit 300, the second embodiment is identical to the first embodiment in other configurations. Therefore, redundant explanations will be omitted.

As shown in FIG. 6, the invalidation circuit 200a differs from the invalidation circuit 200 shown in FIG. 2 in that the inverter 204 is deleted and in that an inverter 205 that inverts the output from the SR latch circuit 210 is added. The invalidation circuit 200a is identical to the invalidation circuit 200 shown in FIG. 2 in other configurations.

With this configuration, when the phase determination signal PD0 is at a low level, then the SR latch circuit 210 is in a set state irrespective of the logic level of the reset signal RST, and the phase determination signal PD1 output from the invalidation circuit 200a is at a low level. On the other hand, when both the reset signal RST and the phase determination signal PD0 are at a high level, then the SR latch circuit 210 is in a reset state, and the phase determination signal PD1 output from the invalidation circuit 200a is at a high level.

Consequently, after resetting of the SR latch circuit 210, when the phase determination signal PD0 is at a low level, the SR latch circuit 210 is set. Thereafter, even when the phase determination signal PD0 changes to be a high level, the change is made invalid. That is, until the SR latch circuit 210 is reset after being set, the level of the phase determination signal PD1 output from the invalidation circuit 200a is fixed to low when the phase determination signal PD0 is at a low level even once. In addition, the state where the phase determination signal PD1 is at a high level is limited to a period in which the phase determination signal PD0 is kept at a high level after the SR latch circuit 210 is reset.

Furthermore, as shown in FIG. 7, while the pitch adjustment circuit 300a differs from the pitch adjustment circuit 300 shown in FIG. 3 in that an inverter 304 that inverts the phase determination signal PD0 is added, the pitch adjustment circuit 300a is identical to the pitch adjustment circuit 300 in other configurations.

With this configuration, when the reset signal DLL_Reset is at a high level, then the SR latch circuit 310 is in a reset state irrespective of the logic level of the phase determination signal PD0, and the pitch designation signal LATOUT output from the SR latch circuit 310 is at a high level. On the other hand, when the reset signal DLL_Reset is at a low level and the phase determination signal PD0 is at a high level, then the SR latch circuit 310 is in a set state and the pitch designation signal LATOUT output therefrom is at a low level. That is, after resetting of the SR latch circuit 310, when the phase determination signal PD0 changes from a low level to a high level, the pitch designation signal LATOUT is at a low level.

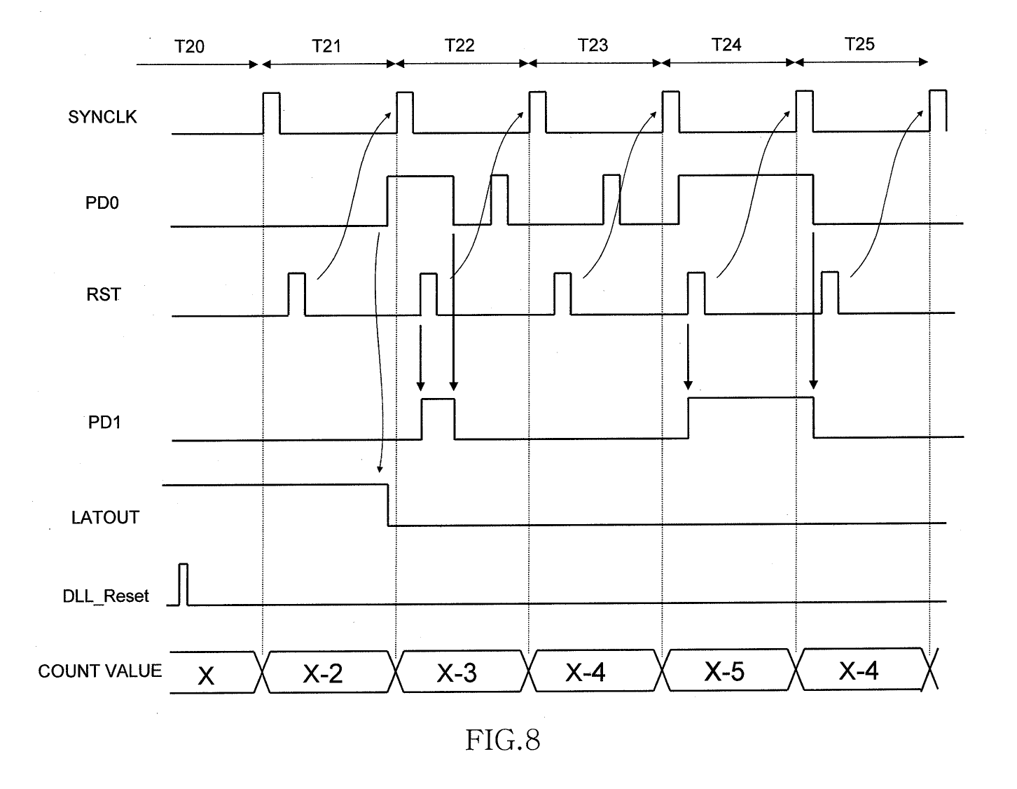

FIG. 8 is a timing chart showing an operation of a DLL circuit according to the second embodiment.

First, when the reset signal DLL_Reset that is a one-shot pulse is activated in a period T20, the pitch designation signal LATOUT is at a high level. As a result, the update pitch of the counter circuit 130 is set to be twice as high as the minimum pitch. In the example shown in FIG. 8, the level of the phase determination signal PD0 has a transition from low to high halfway along a sampling cycle T21, and the pitch designation signal LATOUT turns to at a low level at the transition timing. The update pitch of the counter circuit 130 is thereby set to the minimum pitch.

As shown in FIG. 8, the phase determination signal PD0 is at a low level at timings at which the reset signal RST is activated in sampling cycles T21, T23, and T25, respectively. Accordingly, the SR latch circuit 210 included in the invalidation circuit 200a is not reset. In this case, the SR latch circuit 210 is kept in the set state as before. Accordingly, even when the phase determination signal PD0 changes to a high level halfway as shown in the sampling cycle T23, then such a change is made invalid and the phase determination signal PD1 is kept at a low level. As a result, at a next timing at which the update timing signal SYNCLK is updated, the count value of the counter circuit 130 is forcibly counted down. That is, the delay amount of the delay line 110 is forcibly decreased.

On the other hand, at timings at which the reset signal RST is activated in sampling cycles T22 and T24, the phase determination signal PD0 is at a high level and the SR latch circuit 210 is therefore reset synchronously with the reset signal RST. The phase determination signal PD1 output from the invalidation circuit 200a thereby changes to be a high level.

However, in the sampling cycle T22, the phase determination signal PD0 then changes to be a low level, and therefore the SR latch circuit 210 is made in the set state again in response to the change of the phase determination signal PD0. The phase determination signal PD1 thereby returns to a low level. Thereafter, even when the phase determination signal PD0 changes to be a high level in the same sampling cycle, then such a change is made invalid and the phase determination signal PD1 is kept at a low level. As a result, at a next timing at which the update timing signal SYNCLK is activated, the count value of the counter circuit 130 is forcibly counted down. That is, the delay amount of the delay line 110 is forcibly decreased.

Meanwhile, in the sampling cycle T24, after the SR latch circuit 210 is reset by activation of the reset signal RST, the phase determination signal PD0 is kept to be a high level until a next timing at which the update timing signal SYNCLK is activated. The SR latch circuit 210 is thereby kept in the reset state, and therefore the count value of the counter circuit 130 is increased, that is, the count value of the counter circuit 130 is counted up at a next timing at which the update timing signal SYNCLK is activated. That is, the delay amount of the delay line 110 is increased.

In this manner, in the second embodiment, the case where the count value of the counter circuit 130 is counted up is limited to the case shown in the sampling cycle T24, that is, the case where the phase determination signal PD0 is kept at a high level after the SR latch circuit 210 is reset by activation of the reset signal RST until the next timing at which the update timing signal SYNCLK is activated. In other cases, the invalidation circuit 200a invalidates any changes in the phase determination circuit PD0 and the count value of the counter circuit 130 is forcibly counted down.

Accordingly, the second embodiment can achieve effects identical to those of the first embodiment.

In the second embodiment, a higher priority is given to counting-down of the counter circuit 130 than counting-up thereof. Accordingly, even when it takes a shorter time to lock the DLL circuit 100 by allowing the counter circuit 130 to count up (when the delay amount of the replica clock signal RCLK with respect to the external clock signal CLK is larger than the advanced amount thereof), the DLL circuit 100 is often locked by allowing the counter circuit 130 to continue counting down. In this case, although a slightly longer time is taken before the DLL circuit 100 is locked, at least the problem that the DLL circuit 100 falls into a loop of alternately repeating counting up and down does not occur. Besides, the adjustment operation of adjusting the update pitch of the counter circuit 130 is performed at the update pitch twice as high as the minimum pitch until the active edge of the replica clock signal RCLK exceeds that of the external clock signal CLK. Therefore, it is possible to complete locking the DLL circuit 100 within the period specified by the standards.

A third embodiment of the present invention is explained next.

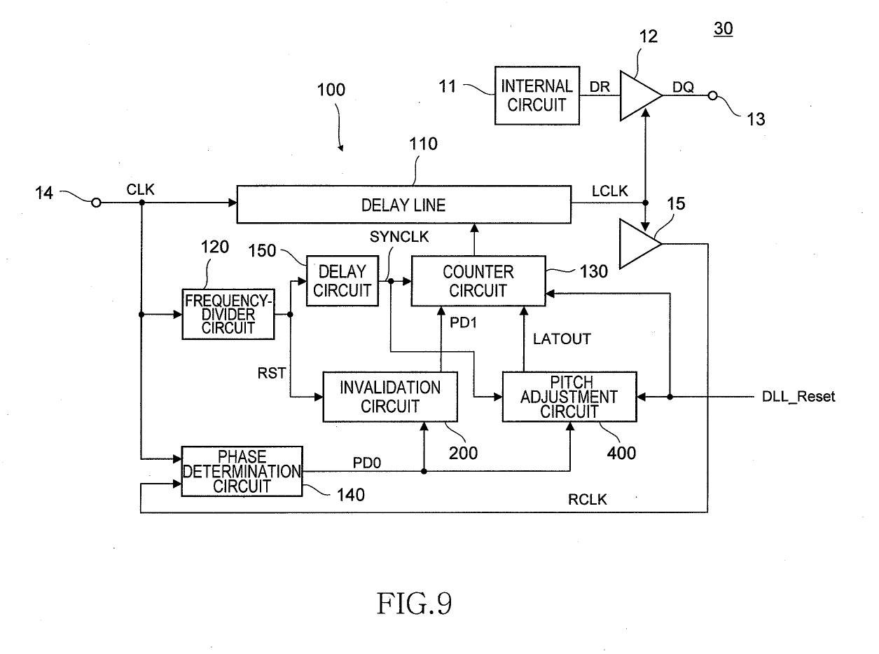

FIG. 9 is a block diagram showing a configuration of a semiconductor device 30 according to the third embodiment. The third embodiment differs from the first embodiment in that a pitch adjustment circuit 400 replaces the pitch adjustment circuit 300. Other configurations of the semiconductor device 30 are identical to those of the semiconductor device 10 according to the first embodiment, and thus like elements are denoted by like reference characters and redundant explanations thereof will be omitted.

As shown in FIG. 9, not only the phase determination signal PD0 and the reset signal DLL_Reset but also the update timing signal SYNCLK is input to the pitch adjustment circuit 400.

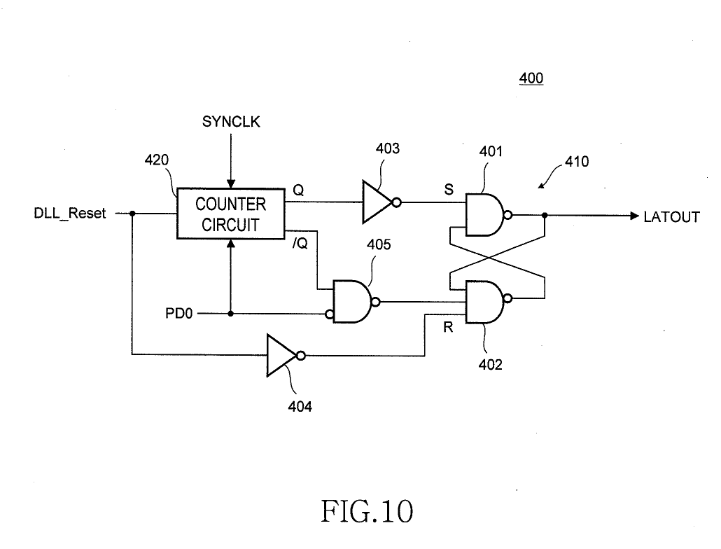

FIG. 10 is a circuit diagram of the pitch adjustment circuit 400.

As shown in FIG. 10, the pitch adjustment circuit 400 includes an SR latch circuit 410 constituted by cross-coupled NAND circuits 401 and 402 and a counter circuit 420 that counts phase determination signal PD0 synchronously with the update timing signal SYNCLK. The counter circuit 420 is a circuit that is reset in response to the reset signal DLL_Reset and changes a detection signal Q from a low level to a high level when the logic level of the phase determination signal PD0 at the time of activating the update timing signal SYNCLK is high four times in a row. The detection signal Q is inverted by an inverter 403 and then input to a set input terminal (S) of the SR latch circuit 410.

The reset signal DLL_Reset is inverted by an inverter 404 and then input to a reset input terminal (R) of the SR latch circuit 410. Moreover, an inverted signal /Q of the detection signal Q and the inverted phase determination signal PD0 are supplied to a NAND circuit 405, and an output from the NAND circuit 405 is input to the reset input terminal (R) of the SR latch circuit 410.

With this configuration, when the reset signal DLL_Reset is at a high level, then the SR latch circuit 410 is in a reset state, and the pitch designation signal LATOUT output from the SR latch circuit 410 is at a low level. Thereafter, when the logic level of the phase determination signal PD0 at the time of activating the update timing signal SYNCLK is high four times in a row, then the SR latch circuit 410 is set, and the pitch designation signal LATOUT output from the SR latch circuit 410 changes to be a high level. Furthermore, when the phase determination signal PD0 changes to be a low level, then the SR latch circuit 410 is reset again, and the designation signal LATOUT output from the SR latch circuit 410 returns to be a low level.

In this case, “the logic level of the phase determination signal PD0 at the time of activating the update timing signal SYNCLK is high four times in a row” means the following state. Because of a large phase shift, when the counter circuit 420 continues to count up at the same update pitch, it is highly likely that it takes a long time before the DLL circuit 100 is locked. In this case, the update pitch is preferably increased so as to lock the DLL circuit 100 more quickly. From these viewpoints, when this condition is detected, the level of the pitch designation signal LATOUT is changed from low to high.

On the other hand, “the phase determination signal PD0 changes to be a low level after the SR latch circuit 410 is set” means a state where the active edge of the replica clock signal RCLK exceeds that of the external clock signal CLK. In this case, the update pitch is preferably decreased so as to correctly lock the DLL circuit 100. From these viewpoints, when this condition is detected, the level of the pitch designation signal LATOUT is changed from high to low.

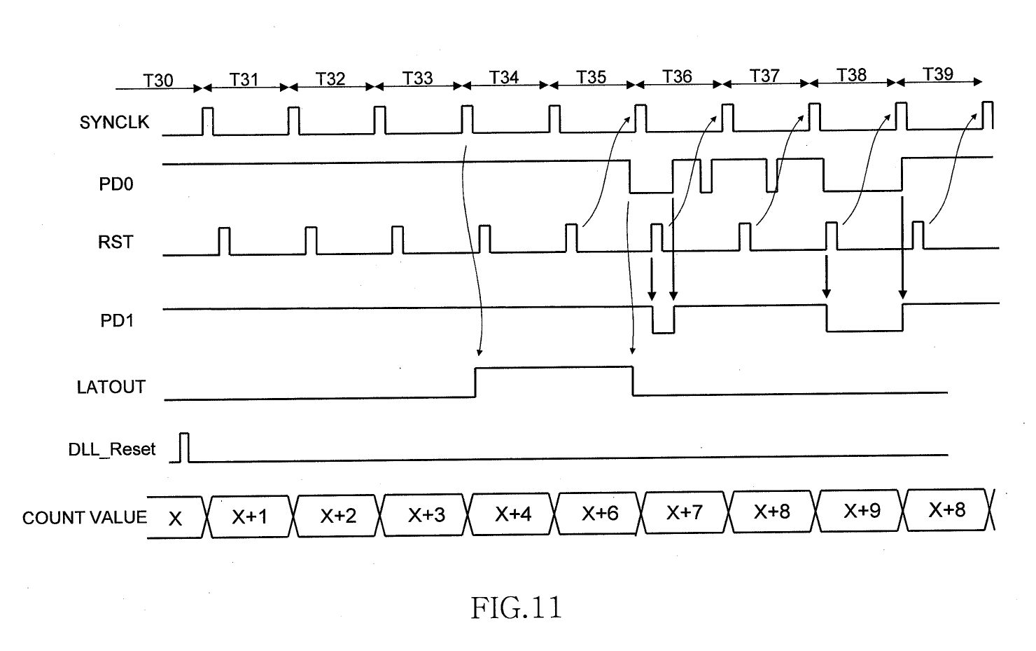

FIG. 11 is a timing chart showing an operation of a DLL circuit according to the third embodiment.

First, when the reset signal DLL_Reset that is a one-shot pulse is activated in a period T30, the pitch designation signal LATOUT is at a low level. The update pitch of the counter circuit 130 is thereby set to the minimum pitch. At this time, because the phase determination signal PD0 is at a high level, the counter circuit 130 is counted up synchronously with the update timing signal SYNCLK.

In an example shown in FIG. 11, after the period T30, the logic level of the phase determination signal PD0 is high four times in a row at the time of activating the update timing signal SYNCLK. In response to this, the pitch designation signal LATOUT changes to be a high level and the update pitch of the counter circuit 130 is set to be twice as high as the minimum pitch (X+4→X+6).

Subsequent operations are identical to those shown in FIG. 5. For example, in a sampling cycle T36, the phase determination signal PD0 changes to be a high level halfway along the period. Accordingly, even when the phase determination signal PD0 changes to be a low level in the same sampling cycle, then such a change is made invalid and the phase determination signal PD1 is kept at a high level.

As described above, in the third embodiment, the update pitch of the counter circuit 130 is set to the minimum pitch right after activation of the reset signal DLL_Reset. Thereafter, when the condition where the logic level of the phase determination signal PD0 at the time of activation of the update timing signal SYNCLK is high four times in a row appears, the update pitch is set twice as high as the minimum pitch. By doing so, the third embodiment can exhibit the following advantage. When the counter circuit 130 continues to count up at the minimum pitch, it takes a long time before the DLL circuit 100 is locked. According to the third embodiment, in contrast, the adjustment operation is performed at an update pitch twice as high as the minimum pitch and thus it is possible to quickly complete locking the DLL circuit 100.

Furthermore, when the phase determination signal PD0 changes to be a low level after the update pitch of the counter circuit 130 is set twice as high as the minimum pitch, the update pitch is returned to the minimum pitch. Therefore, it is possible to avoid performing an adjustment operation excessively in a state where the DLL circuit 100 is locked soon.

A fourth embodiment of the present invention is explained next.

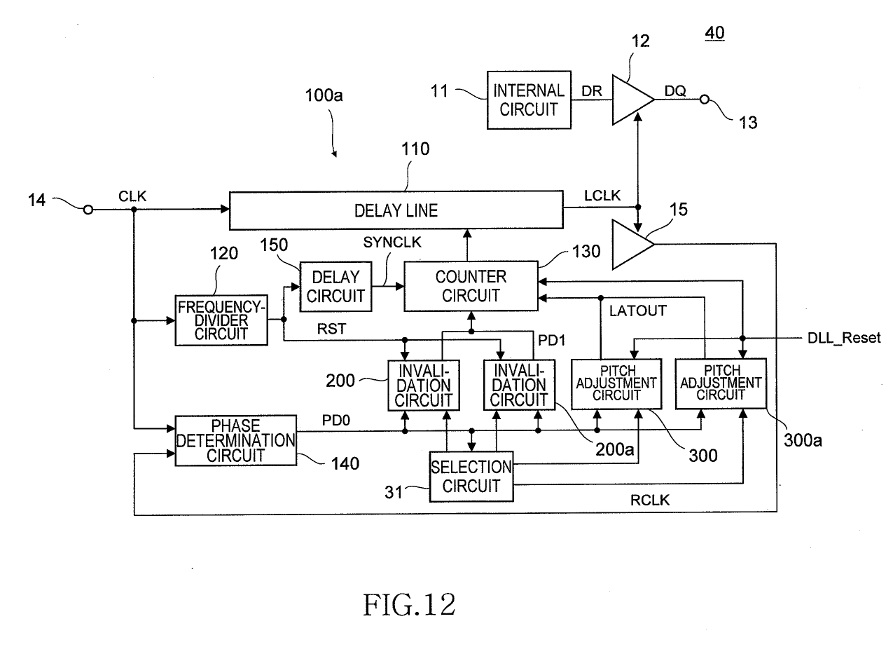

FIG. 12 is a block diagram showing a configuration of a semiconductor device 40 according to the fourth embodiment. The fourth embodiment differs from the first embodiment in that a DLL circuit 100a includes both of invalidation circuits 200 and 200a, both of pitch adjustment circuits 300 and 300a, and a selection circuit 31 that selects one of the invalidation circuits 200 and 200a and one of the pitch adjustment circuits 300 and 300a. Other configurations of the semiconductor device 40 are identical to those of the semiconductor device 10 according to the first embodiment, and thus like elements are denoted by like reference characters and redundant explanations thereof will be omitted.

As shown in FIG. 12, the phase determination signal PD0 output from the phase determination circuit 140 is input to the selection circuit 31. The selection circuit 31 selects one of the invalidation circuits 200 and 200a and one of the adjustment circuits 300 and 300a based on the logic level of a first acquired phase determination signal PD0 after the DLL circuit 100a starts operating. Outputs from the unselected invalidation circuit and pitch adjustment circuit are ignored. Specifically, when the first acquired phase determination signal PD0 is at a high level, the selection circuit 31 selects the invalidation circuit 200 and the pitch adjustment circuit 300 that give a higher priority to counting-up of the counter circuit 130, and when the first acquired phase determination signal PD0 is at a low level, the selection circuit 31 selects the invalidation circuit 200a and the pitch adjustment circuit 300a that give a higher priority to counting-down of the counter circuit 130.

When the first acquired phase determination signal PD0 is at a high level, there is a high probability that it takes a shorter time to lock the DLL circuit 100a by allowing the counter circuit 130 to count up (the delay amount of the replica clock signal RCLK with respect to the external clock signal CLK is larger than the advanced amount thereof). Conversely, when the first acquired phase determination signal PD0 is at a low level, there is a high probability that it takes a shorter time to lock the DLL circuit 100a by allowing the counter circuit 130 to count down (the advanced amount of the replica clock signal RCLK with respect to the external clock signal CLK is larger than the delay amount thereof). Accordingly, when the selection circuit 31 selects one of the invalidation circuits 200 and 200a and one of the pitch adjustment circuits 300 and 300a based on the first acquired phase determination signal PD0, it is possible to lock the DLL circuit 100a more quickly than the first and second embodiments.

Note that a pitch adjustment circuit of the type (the pitch adjustment circuit 400) shown in FIG. 10 can replace the pitch adjustment circuit 300 or 300a.

A fifth embodiment of the present invention is explained next.

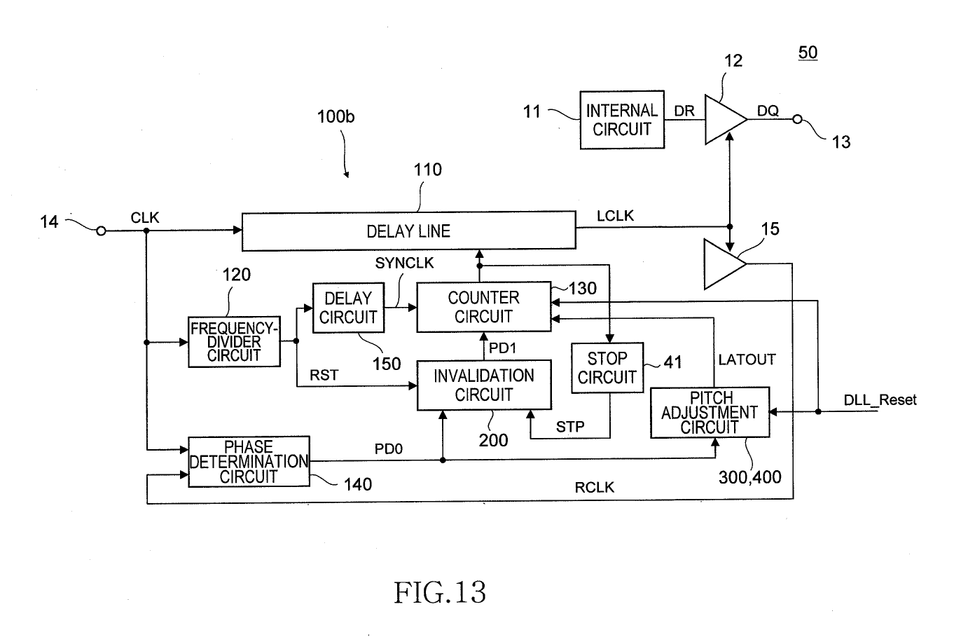

FIG. 13 is a block diagram showing a configuration of a semiconductor device 50 according to the fifth embodiment. The fifth embodiment differs from the first or third embodiment in that a DLL circuit 100b includes a stop circuit 41 that stops the invalidation circuit 200 from performing an invalidation operation described above. Other configurations of the semiconductor device 50 are identical to those of the semiconductor devices 10 and 30 according to the first and third embodiment, respectively, and thus like elements are denoted by like reference characters and redundant explanations thereof will be omitted.

A stop signal STP output from the stop circuit 41 is inactive in an initial state. Accordingly, the invalidation circuit 200 performs the invalidation operation described above. The count value of the counter circuit 130 is supplied to the stop circuit 41. When this count value changes in a preset pattern, the stop signal STP is set active. When the stop signal STP is activated, the invalidation circuit 200 stops performing the invalidation operation and supplies the phase determination signal PD0 to the counter circuit 130 as the phase determination signal PD1 without processing the phase determination signal PD0.

The “preset pattern” represents a pattern that appears in a state where the DLL circuit 100b is locked or close to be locked. Specifically; when a pattern in which the count value of the counter circuit 130 is counted down after being counted up or an opposite pattern appears, it is preferable to activate the stop signal STP. This is because appearance of such a pattern is indicative of a case where the external clock CLK and the replica clock RCLK are almost matched to each other in phase. In such a case, when the invalidation circuit 200 preferentially counts up, a phase shift possibly occurs. Therefore, in the fifth embodiment, the stop circuit 41 stops the invalidation circuit 200 from performing the invalidation operation.

Therefore, according to the fifth embodiment, it is possible to attain an advantage of being capable of further ensuring that a locked state after locking the DLL circuit 100b can be held in addition to the advantages of the first embodiment.

As for the preset pattern, that is, change pattern of the count value for activating the stop signal STP, a pattern in which the counter circuit 130 alternately repeats counting up and down three times or four or more times can be used besides the pattern mentioned above. This is because the fact that the counter circuit 130 alternately repeats counting up and down is more clearly indicative of the case where the external clock CLK and the replica clock RCLK are almost matched to each other in phase.

A sixth embodiment of the present invention is explained next.

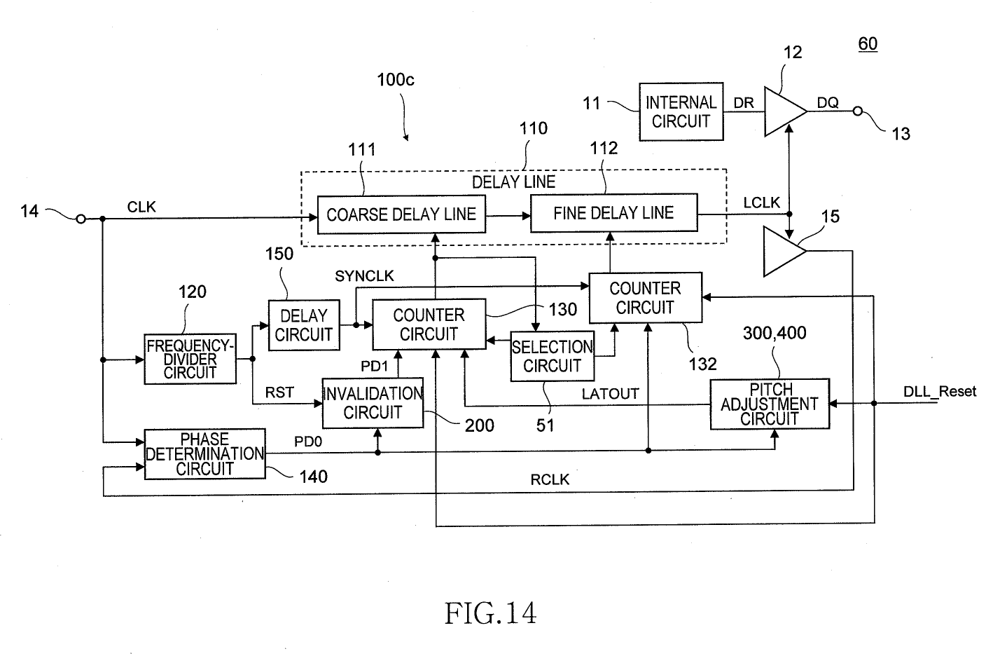

FIG. 14 is a block diagram showing a configuration of a semiconductor device 60 according to the sixth embodiment. The sixth embodiment differs from the first or third embodiment in that the delay line 110 includes a coarse delay line 111 and a fine delay line 112, a DLL circuit 100c includes a counter circuit 132 that adjusts a delay amount of the fine delay line 112, and the DLL circuit 100c includes a selection circuit 51 that selects one of counter circuits 130 and 132. Other configurations of the semiconductor device 60 are identical to those of the semiconductor devices 10 and 30 according to the first and third embodiment, respectively, and thus like elements are denoted by like reference characters and redundant explanations thereof will be omitted.

The coarse delay line 111 is a delay line for which an adjustment pitch of adjusting the delay amount is relatively coarse and constituted by an inverter chain in which inverters relatively having large delay amounts are cascaded. The fine delay line 112 is a delay line for which an adjustment pitch of adjusting the delay amount is relatively fine and constituted by an inverter chain in which inverters relatively having small delay amounts are cascaded or by an interpolator that combines two clocks obtained from the coarse delay line 111.

In the sixth embodiment, the delay amount of the coarse delay line 111 is adjusted based on the count value of the counter circuit 130 whereas the delay amount of the fine delay line 112 is adjusted based on a count value of the counter circuit 132. The coarse delay line 111 and the fine delay line 112 are connected in series. After the coarse delay line 111 makes a coarse adjustment of the delay amount, the fine delay line 112 makes a finer adjustment of the delay amount, thereby realizing quick and highly accurate locking of the DLL circuit 100c.

As shown in FIG. 14, the phase determination signal PD1 via the invalidation circuit 200 is supplied to the counter circuit 130 that controls the coarse delay line 111 whereas the phase determination signal PD0 is directly supplied to the counter circuit 132 that controls the fine delay line 112. The reason is as follows. Because the fine delay line 112 is used mainly for the fine adjustment after locking the DLL circuit 100c, the fine delay line 112 does not have a great effect on time since an unlocked state until locking of the DLL circuit 100c. When the invalidation operation is performed on the fine delay line 112, a phase shift is likely to rather increase.

The pitch adjustment circuits 300 and 400 change the update pitch of the counter circuit 130 that controls the coarse delay line 111 whereas an update pitch of the counter circuit 132 that controls the fine delay line 112 is not changed but kept constant. This is because there is less need to change the update pitch of the counter circuit 132 because the fine delay line 112 is used mainly for the fine adjustment after locking the DLL circuit 100c as described above.

The selection circuit 51 is a circuit that permits one of the counter circuits 130 and 132 to operate (one of count values thereof to be updated). In an initial state, the selection circuit 51 selects the counter circuit 130, whereby the delay line 110 allows the coarse delay line 111 to perform a coarse adjustment operation. The count value of the counter circuit 130 is supplied to the selection circuit 51. When this count value changes in a preset pattern, the selection circuit 51 stops the counter circuit 130 from operating, selects the counter circuit 132 in place of the counter circuit 130, and allows the fine delay line 112 to make the fine adjustment. Examples of the preset pattern include the same pattern as the pattern of activating the stop signal STP described above.

According to the sixth embodiment, it is thereby possible to quickly lock the DLL circuit 100c and ensure a highly accurate DLL locked state because of no influence of the operation performed by the invalidation circuit 200 on the fine delay line 112.

A seventh embodiment of the present invention is explained next.

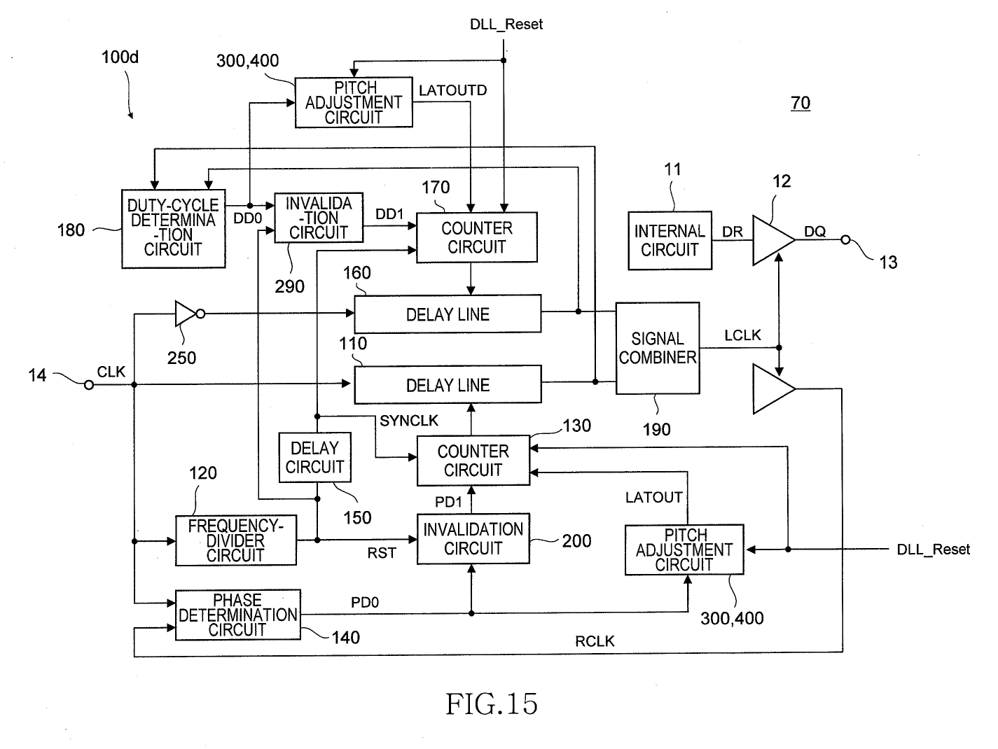

FIG. 15 is a block diagram showing a configuration of a semiconductor device 70 according to the seventh embodiment.

As shown in FIG. 15, the semiconductor device 70 according to the seventh embodiment further includes a delay line 160, a counter circuit 170, a duty-cycle determination circuit 180, and an invalidation circuit 290. A signal combiner 190 combines outputs from the two delay lines 110 and 160, thereby generating the internal clock signal LCLK. Furthermore, the pitch adjustment circuits 300 and 400 are allocated to the counter circuit 170. Other configurations of the semiconductor device 70 are identical to those of the semiconductor devices 10 according to the first embodiment, and thus like elements are denoted by like reference characters and redundant explanations thereof will be omitted.

The delay line 160 and the counter circuit 170 constitute a duty-cycle correction circuit that corrects a duty cycle of the external clock signal CLK inverted by an inverter 250. Specifically, the delay line 160 adjusts a position of a falling edge of the external clock signal CLK, thereby adjusting the duty cycle of the internal clock signal LCLK. The counter circuit 170 sets an adjustment amount by which the duty cycle of the internal clock signal LCLK is adjusted. On the other hand, the delay line 110 adjusts a position of a rising edge of the external clock signal CLK, thereby adjusting a phase of the internal clock signal LCLK. The signal combiner 190 thereby generates the internal clock signal LCLK the phase and the duty cycle of which are both accurately adjusted.

The counter circuit 170 is a circuit that sets a delay amount of the delay line 160, and a count value of the counter circuit 170 is updated synchronously with the update timing signal SYNCLK. An increase or a decrease in the count value is set based on a duty-cycle determination signal DD1 supplied from the invalidation circuit 290. That is, when the duty-cycle determination signal DD1 indicates counting-up, the count value of the counter circuit 170 is counted up synchronously with the update timing signal SYNCLK, thereby increasing the delay amount of the delay line 160. On the other hand, when the duty-cycle determination signal DD1 indicates counting-down, the count value of the counter circuit 170 is counted down synchronously with the update timing signal SYNCLK, thereby decreasing the delay amount of the delay line 160.

The invalidation circuit 290 is a circuit that receives a duty-cycle determination signal DD0 and the reset signal RST and generates the duty-cycle signal DD1 based on these signals DD0 and RST. The invalidation circuit 290 is similar in circuit configuration to the invalidation circuit 200 shown in FIG. 2 or the invalidation circuit 200a shown in FIG. 6. Therefore, the invalidation circuit 290 performs invalidation operations similar to those of the invalidation circuit 200 or 200a.

The duty-cycle determination circuit 180 is a circuit that detects the duty cycle of the internal clock signal LCLK based on the outputs from the delay lines 110 and 160 and generates the duty-cycle determination signal DD0 corresponding to the detected duty cycle.

Furthermore, the pitch adjustment circuits 300 and 400 allocated to the counter circuit 170 generate a pitch designation signal LATOUTD based on the duty-cycle determination signal DD0, and an update pitch of the counter circuit 170 is changed based on the pitch designation signal LATOUTD. Basic operations of the pitch adjustment circuits 300 and 400 are as described above.

As described above, the DLL circuit 100d according to the seventh embodiment employs the invalidation circuit 200 to eliminate a component such as noise or a jitter component that affects the phase determination signal PD0 in a short cycle, and employs the invalidation circuit 290 to eliminate a component that affects the duty-cycle determination signal DD0 in a short cycle. Besides, the DLL circuit 100d employs the pitch adjustment circuits 300 and 400 allocated to the counter circuit 170 to make the update pitch of the counter circuit 170 variable. With this configuration, it is possible to quickly adjust not only a phase but also a duty cycle.

It is apparent that the present invention is not limited to the above embodiments, but may be modified and changed without departing from the scope and spirit of the invention.

For example, the respective embodiments have been described while referring to a case of applying the present invention to a DLL circuit as an example. However, the application target of the present invention is not limited to DLL circuits, and the present invention can be also applied to a clock control circuit of other types, for example, a duty-cycle correction circuit (see FIG. 15).

In the respective embodiments, the invalidation circuit 200 or the like is reset using the reset signal RST. Alternatively, the update timing signal SYNCLK itself can be used as the reset signal RST as long as update timing signal SYNCLK does not interfere with the update operation of the counter circuit 130. In addition, the reset signal RST can be generated by delaying the update timing signal SYNCLK.

In the respective embodiments, a relatively low update pitch is defined as the minimum pitch and a relatively high update pitch is defined as the update pitch twice as high as the minimum pitch. However, the present invention is not limited thereto, and an arbitrary combination of two update pitches can be defined as the minimum pitch and the pitch twice as high as the minimum pitch as long as there is a difference between the two update pitches. For example, a relatively low update pitch can be defined as the minimum pitch whereas a relatively high update pitch can be defined as an update pitch four or eight times as high as the minimum pitch.

In addition, an invalidation circuit has been used in the respective embodiments; however, in the present invention, providing an invalidation circuit is not essential, and it can be omitted as far as a pitch adjustment circuit is used.

In addition, while not specifically claimed in the claim section, the applicant reserves the right to include in the claim section of the application at any appropriate time the following clock control circuits:

A1. A clock control circuit comprising:

a phase determination circuit that generates a phase determination signal based on a phase of a first clock signal;

a counter circuit having a count value updated based on a logic level of the phase determination signal;

a delay line that generates a second clock signal by delaying the first clock signal based on the count value; and

a pitch adjustment circuit that sets an update pitch of the counter circuit to a first pitch in a period in which the phase determination signal has no change, and sets the update pitch of the counter circuit to a second pitch in response to a change in the phase determination signal, where the first pitch being a relatively large pitch and the second pitch being a relatively small pitch.

A2. The clock control circuit as A1, wherein the pitch adjustment circuit sets the update pitch of the counter circuit to the first pitch when the phase determination signal has no change for a predetermined period.

B1. A clock control circuit comprising:

a phase determination circuit that generates a phase determination signal based on a phase of a first clock signal;

a counter circuit having a count value updated based on a logic level of the phase determination signal;

a delay line that generates a second clock signal by delaying the first clock signal based on the count value; and

a pitch adjustment circuit that changes an update pitch of the counter circuit from a relatively small pitch to a relatively large pitch when the phase determination signal has no change for a predetermined period.

What is claimed is:

1. A clock control circuit comprising:
a phase determination circuit that generates a phase determination signal based on a phase of a first clock signal;
a counter circuit having a count value updated for every sampling cycle based on the phase determination signal;
a first delay line that generates a second clock signal by delaying the first clock signal based on the count value;
a first invalidation circuit that invalidates a subsequent change of the phase determination signal in a same sampling cycle in response to a fact that the phase determination signal indicates a first logic level; and
a first pitch adjustment circuit that changes an update pitch of the counter circuit in response to a fact that the phase determination signal indicates a second logic level.

2. The clock control circuit as claimed in claim 1, wherein the first pitch adjustment circuit decreases the update pitch of the counter circuit in response to a fact that the phase determination signal indicates the second logic level.

3. The clock control circuit as claimed in claim 2, wherein
the first pitch adjustment circuit includes a first SR latch circuit that is reset synchronously with a first reset signal for resetting the counter circuit and is set in response to the second logic level of the phase determination signal, and
the update pitch of the counter circuit is set to be relatively large since the first reset signal is activated until the phase determination signal indicates the second logic level, and the update pitch of the counter circuit is set to be relatively small in response to a fact that the phase determination signal indicates the second logic level.

4. The clock control circuit as claimed in claim 1, wherein the first pitch adjustment circuit changes the update pitch of the counter circuit when the phase determination signal does not change for a predetermined number of sampling cycles.

5. The clock control circuit as claimed in claim 4, wherein the first pitch adjustment circuit increases the update pitch of the counter circuit when the phase determination signal does not change for the predetermined number of the sampling cycles.

6. The clock control circuit as claimed in claim 1, wherein
the first invalidation circuit includes a second SR latch circuit that is reset synchronously with a second reset signal activated for every sampling cycle and is set in response to the first logic level of the phase determination signal, and
the first invalidation circuit invalidates a change of a level of the phase determination signal to the second logic level for a period after setting the second SR latch circuit until resetting the second SR latch circuit.

7. The clock control circuit as claimed in claim 1, further comprising a stop circuit that stops an invalidation operation of the first invalidation circuit so as to supply the phase determination signal output from the phase determination circuit to the counter circuit without processing by the first invalidation circuit.

8. The clock control circuit as claimed in claim 1, wherein
the first delay line includes:
a coarse delay line in which an adjustment pitch for adjusting the delay amount is relatively large; and
a fine delay line in which an adjustment pitch for adjusting the delay amount is relatively small, and
the counter circuit adjusts the delay amount of the coarse delay line included in the first delay line.

9. The clock control circuit as claimed in claim 1, further comprising:
a second invalidation circuit that invalidates a subsequent change in the phase determination signal in a same sampling cycle in response to a fact that the phase determination signal indicates the second logic level;
a second pitch adjustment circuit that changes an update pitch of the counter circuit in response to a fact that the phase determination signal indicates the first logic level; and
a selection circuit that selects one of the first and second invalidation circuits and one of the first and second pitch adjustment circuits.

10. The clock control circuit as claimed in claim 1, further comprising:
a duty-cycle determination circuit that generates a duty-cycle determination signal based on a duty cycle of the second clock signal;
a duty-cycle correction circuit that corrects a duty cycle of the second clock signal based on the duty-cycle determination signal; and
a third pitch adjustment circuit that changes a duty-cycle correcting pitch of the duty-cycle correction circuit in response to a fact that the duty-cycle determination signal indicates a predetermined one of the first and second logic levels.

11. The clock control circuit as claimed in claim 1, wherein the phase determination circuit determines a phase of the first clock signal by comparing a third clock signal obtained by delaying the second clock signal with the first clock signal.

12. A semiconductor device comprising:
a clock control circuit that receives a first clock signal to generate a second clock signal;
an output buffer that outputs an external output signal synchronously with the second clock signal; and
a replica buffer that is substantially identical in circuit configuration to the output buffer, and outputs a third clock signal synchronously with the second clock signal,
wherein the clock control circuit comprising:
a phase determination circuit that generates a phase determination signal based on a phase of a first clock signal;
a counter circuit having a count value updated for every sampling cycle based on the phase determination signal;
a first delay line that generates a second clock signal by delaying the first clock signal based on the count value;
a first invalidation circuit that invalidates a subsequent change of the phase determination signal in a same sampling cycle in response to a fact that the phase determination signal indicates a first logic level; and
a first pitch adjustment circuit that changes an update pitch of the counter circuit in response to a fact that the phase determination signal indicates a second logic level, and
wherein the phase determination circuit determines a phase of the first clock signal by comparing the third clock signal with the first clock signal.

13. A semiconductor device comprising:
a delay line adding an adjustable amount of delay to an external clock to produce a first clock signal;
a replica circuit producing a second clock signal in response to the first clock signal;
a phase determination circuit comparing the external clock signal with the second clock signal in phase and outputting a first control signal that takes a first potential when the second clock signal is faster in phase than the external clock signal and a second potential when the external clock signal is faster in phase than the second clock signal; and
a delay line control circuit decreasing the adjustable amount of delay in a first condition that the first control signal keeps taking the second potential through a determination period, and not decreasing the adjustable amount of delay even though the first control signal changes in potential from the first potential to the second potential in the determination period.

14. The semiconductor device as claimed in claim 13, wherein the delay line control circuit receives a reset pulse defining a start of the determination period and a timing pulse defining an end of the determination period.

15. The semiconductor device as claimed in claim 14, wherein the delay line control circuit outputs a second control signal to control the adjustable amount of delay, the second control signal taking the second potential when the first control signal takes the second potential while the reset pulse is in activate, and the second control signal not taking the second potential even though the first control signal changes in potential from the first potential to the second potential while the reset pulse is in inactivate.

16. The semiconductor device as claimed in claim 13, wherein the delay line control circuit increases the adjustable amount of delay when the first control signal changes in potential from the first potential to the second potential in the determination period.

17. The semiconductor device as claimed in claim 13, further comprising an external IO terminal and an output circuit outputting data to the external IO terminal, the output circuit and the replica circuit receiving the first clock signal in common, and the output circuit and the replica circuit having substantially the same delay amount as each other.
